(19) United States
(12) Patent Application Publication
(10) Pub. No.: US 2024/0312860 A1
(43) Pub. Date: Sep. 19, 2024

(54) SEMICONDUCTOR DEVICE AND MANUFACTURING METHOD THEREOF

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Daisuke KOIKE, Tama Tokyo (JP); Hisashi TOMITA, Yokohama Kanagawa (JP); Yuning TSAI, Yokohama Kanagawa (JP); Yutaro HAYASHI, Yokohama Kanagawa (JP)

(21) Appl. No.: 18/467,581

(22) Filed: Sep. 14, 2023

(30) Foreign Application Priority Data
Mar. 15, 2023 (JP) 2023-040933

(51) Int. Cl. H01L 23/367; H01L 23/00; H01L 23/373; H01L 29/739

(52) U.S. Cl. CPC H01L 23/367; H01L 23/3736; H01L 24/29; H01L 24/32; H01L 24/83; H01L 29/7393; H01L 2224/29139; H01L 2224/29147; H01L 2224/32245; H01L 2224/83201; H01L 2224/8348

(57) ABSTRACT

A semiconductor device according to an embodiment includes: a semiconductor chip; a conductive sheet provided on the semiconductor chip; and a metal plate provided on the conductive sheet. The metal plate has a step portion that is provided on a lateral surface, or a groove portion that is provided on a bottom surface.

### CROSS-REFERENCE TO RELATED APPLICATIONS

This application is based upon and claims the benefit of priority from Japanese Patent Application No. 2023-040933, filed on Mar. 15, 2023; the entire contents of which are incorporated herein by reference.

### FIELD

Embodiments of the present invention relate to a semiconductor device and a manufacturing method thereof.

### BACKGROUND

A PPI (Press Pack IEGT), which is one of semiconductor devices, is mainly used for a converter for power transmission which performs conversion from AC to DC or conversion from DC to AC. For the PPI, in recent years, the maximum rated value of the junction temperature Tj of the IEGT (Injection Enhanced Gate Transistor) is required to be from 125° C. to 150° C.

A conventional PPI has a structure in which a metal plate such as molybdenum and an IEGT chip are pressure welded. It is however difficult for this structure to satisfy the aforementioned requirement for the junction temperature Tj.

Therefore, a structure is proposed in which the metal plate and the IEGT chip are bonded with a conductive sheet. Since this structure allows improvement of conductivity of heat generated in the IEGT chip, the aforementioned requirement for the junction temperature Tj can be satisfied.

Burrs of the conductive sheet occasionally arise in manufacturing steps of the PPI that includes the aforementioned conductive sheet. In such a case, when some of the burrs come into contact with a control terminal that controls drive of the IEGT chip, short circuit failure can occur. There is therefore a concern of deterioration in reliability.

### BRIEF DESCRIPTION OF THE DRAWINGS

FIG. 1 is a cross sectional view showing a schematic structure of a semiconductor device according to a first embodiment;

FIG. 2 is a cross sectional view showing a schematic structure of a semiconductor chip;

FIG. 3A is a cross sectional view for explaining a processing step of a metal plate according to the first embodiment;

FIG. 3B is a plan view for explaining the processing step of the metal plate according to the first embodiment;

FIG. 3C is a cross sectional view for explaining a picking-up step of the metal plate according to the first embodiment;

FIG. 3D is a cross sectional view for explaining a step of bonding a conductive sheet to the metal plate according to the first embodiment;

FIG. 3E is a cross sectional view for explaining a step of separating a bonding portion to the metal plate from a non-bonding portion thereto, on the conductive sheet according to the first embodiment;

FIG. 4A is a cross sectional view for explaining a picking-up step of a metal plate according to a comparative example;

FIG. 4B is a cross sectional view for explaining a step of bonding a conductive sheet to the metal plate according to the comparative example;

FIG. 4C is a cross sectional view for explaining a step of separating a bonding portion to the metal plate from a non-bonding portion thereto, on the conductive sheet according to the comparative example;

FIG. 4D is a cross sectional view for explaining a step of mounting the metal plate and the conductive sheet onto the semiconductor chip;

FIG. 5A is a cross sectional view for explaining a processing step of a metal plate according to a second embodiment;

FIG. 5B is a plan view for explaining the processing step of the metal plate according to the second embodiment;

FIG. 5C is a lateral view of the metal plate according to the second embodiment as viewed from a YZ-plane;

FIG. 5D is a cross sectional view for explaining a picking-up step of the metal plate according to the second embodiment;

FIG. 5E is a cross sectional view for explaining a step of bonding a conductive sheet to the metal plate according to the second embodiment;

FIG. 5F is a cross sectional view for explaining a step of separating a bonding portion to the metal plate from a non-bonding portion thereto, on the conductive sheet according to the second embodiment;

FIG. 5G is a cross sectional view for explaining a step of mounting the metal plate and the conductive sheet onto the semiconductor chip according to the second embodiment;

FIG. 6A is a cross sectional view for explaining a processing step of a metal plate according to the third embodiment;

FIG. 6B is a plan view for explaining the processing step of the metal plate according to the third embodiment;

FIG. 6C is a cross sectional view for explaining a picking-up step of the metal plate according to the first embodiment;

FIG. 6D is a cross sectional view for explaining a step of bonding a conductive sheet to the metal plate according to the third embodiment;

FIG. 6E is a cross sectional view for explaining a step of separating a bonding portion to the metal plate from a non-bonding portion thereto, on the conductive sheet according to the third embodiment; and

FIG. 6F is a cross sectional view for explaining a step of mounting the metal plate and the conductive sheet onto the semiconductor chip according to the third embodiment.

### DETAILED DESCRIPTION

Embodiments will now be explained with reference to the accompanying drawings. The present invention is not limited to the embodiments.

A semiconductor device according to an embodiment includes: a semiconductor chip; a conductive sheet provided on the semiconductor chip; and a metal plate provided on the conductive sheet. The metal plate has a step portion that is provided on a lateral surface, or a groove portion that is provided on a bottom surface.

### First Embodiment

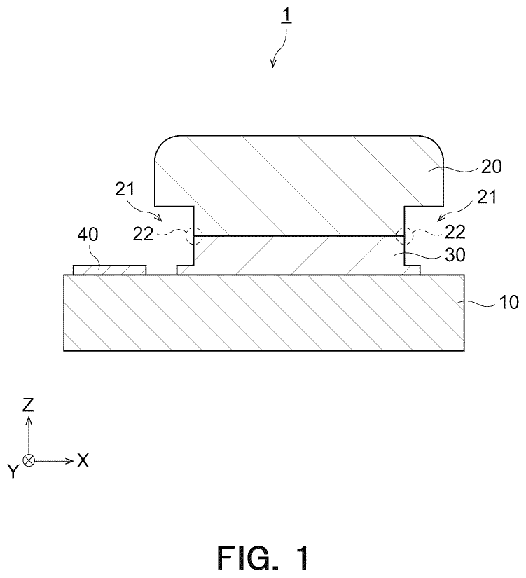

FIG. 1 is a cross sectional view showing a schematic structure of a semiconductor device according to a first embodiment. A semiconductor device 1 shown in FIG. 1 is a PPI. The semiconductor device 1 includes a semiconductor chip 10, a metal plate 20. a conductive sheet 30, and a control terminal 40. Hereafter, there occasionally is a case where arrangements and configurations of individual portions are described using an X-axis, a Y-axis, and a Z-axis shown in the drawings. The X-axis, the Y-axis, and the Z-axis are perpendicular to one another and represent an X-direction, a Y-direction, and a Z-direction, respectively. Moreover, there occasionally is a case where the description is made, regarding the Z-direction as being upward and its reverse direction as being downward.

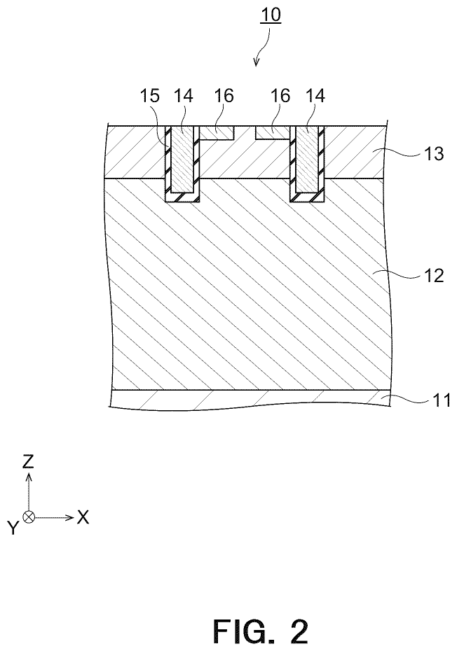

FIG. 2 is a cross sectional view showing a schematic structure of the semiconductor chip 10. The semiconductor chip 10 shown in FIG. 2 is an IEGT. Specifically, the semiconductor chip 10 includes a p-type collector layer 11, an n-type base layer 12, a p-type base layer 13, gate electrodes 14, gate oxide films 15, and n-type emitter layers 16. Notably, the structure of the semiconductor chip 10 is not limited to the structure shown in FIG. 2.

The p-type collector layer 11 is provided on the back surface of the semiconductor chip 10. The n-type base layer 12 is provided on the p-type collector layer 11. The p-type base layer 13 is provided on the n-type base layer 12. In the p-type base layer 13, the gate electrodes 14 and the n-type emitter layers 16 are provided. The gate electrodes 14 and the n-type emitter layers 16 are electrically insulated from each other with the gate oxide films 15.

In the semiconductor chip 10 configured as above, when a predetermined voltage is applied between the gate electrodes 14 and the n-type emitter layers 16, a channel layer is formed in the p-type base layer 13. Via the channel layer, a current flows from the p-type collector layer 11 to the n-type emitter layers 16.

As compared with an IGBT (Insulated Gate Bipolar Transistor), with the semiconductor chip 10, a resistance against carriers that are to pass through to the n-type emitter layers 16 is higher, which restrains such passing-through. As a result, there is obtained an IE (Injection Enhancement) effect that carriers are injected and accumulated in the n-type base layer 12. Accordingly, a voltage drop can be restrained from increasing, even with the withstand voltage made high.

Returning to FIG. 1, the metal plate 20 is provided on the semiconductor chip 10. An example of the metal plate 20 is a molybdenum plate. A step portion 21 recessed inward is formed on a lateral surface of the metal plate 20. Moreover, a lower end corner portion 22 of the step portion 21, in other words, a boundary portion between a lower end portion of the step portion 21 and a bottom surface of the metal plate 20 (surface that faces the semiconductor chip 10) has an angular shape.

The conductive sheet 30 is provided between the semiconductor chip 10 and the metal plate 20. An example of the conductive sheet 30 is a sintered sheet obtained by sintering a metal such as silver or copper. Moreover, the conductive sheet 30 also includes an adhesive agent. The adhesive agent joins the metal plate 20 to the semiconductor chip 10. Thereby, the n-type emitter layers 16 of the semiconductor chip 10 and the metal plate 20 are electrically connected.

The control terminal 40 is provided on the semiconductor chip 10. The control terminal 40 is electrically connected to the gate electrodes 14 of the semiconductor chip 10. Notably, not shown in FIG. 1, an emitter electrode electrically connected to the n-type emitter layers 16 of the semiconductor chip 10 is provided on the metal plate 20. Moreover, a collector electrode electrically connected to the p-type collector layer 11 of the semiconductor chip is provided on the back surface side of the semiconductor chip 10.

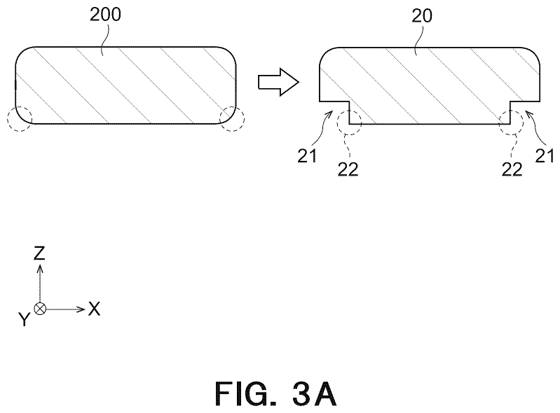

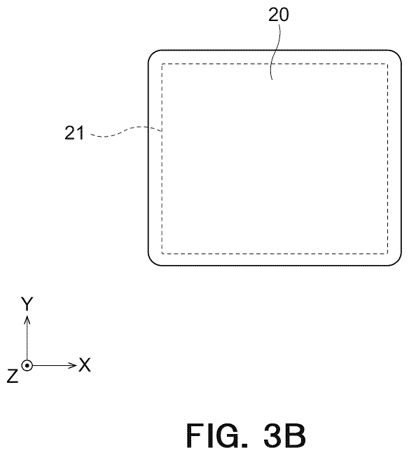

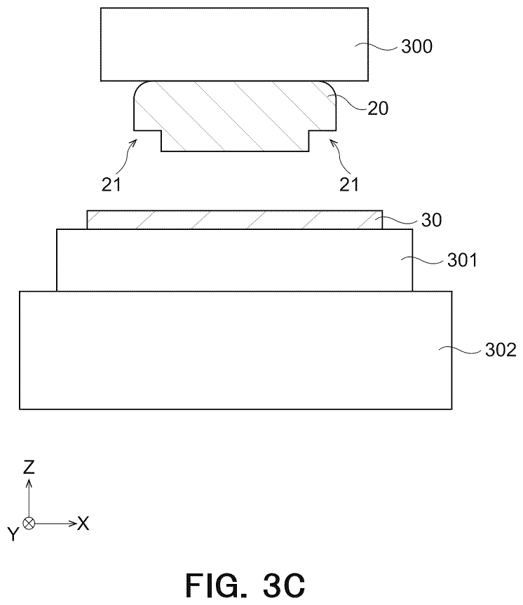

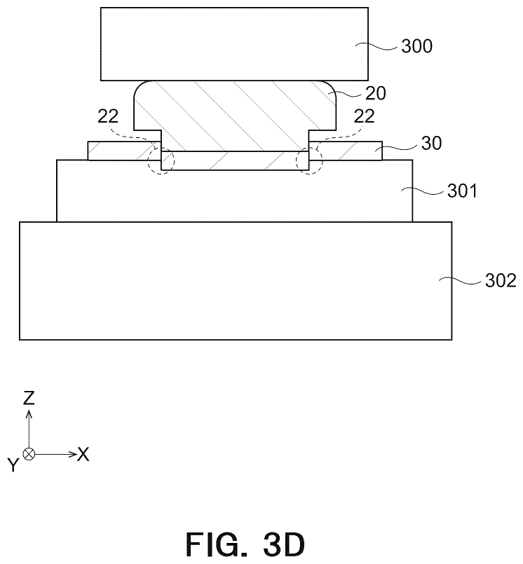

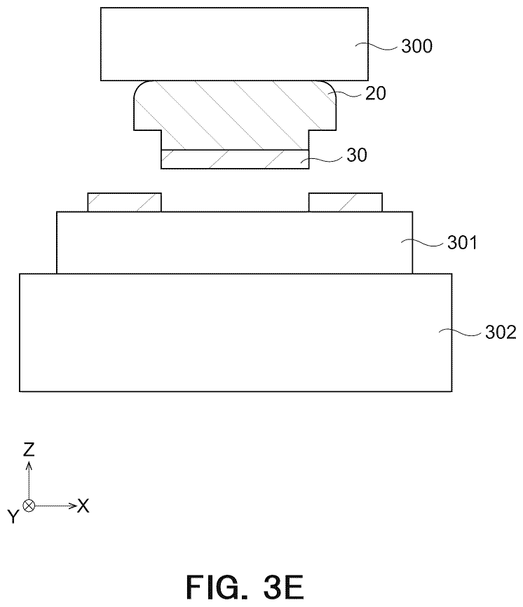

Hereafter, a manufacturing method of the aforementioned semiconductor device 1 according to the first embodiment is described with reference to FIG. 3A to FIG. 3E.

First, as shown in FIG. 3A, a rounded lower end corner portion 201 of a metal plate 200 is cut off, for example, by laser machining. Thereby, the metal plate 200 is processed into the metal plate 20 that has the step portion 21 on the lateral surface.

As shown in FIG. 3B which is a plan view, the step portion 21 is formed around the whole circumference of the lateral surface of the metal plate 20. Moreover, the lower end corner portion 22 of the step portion 21 is processed into an angular shape.

Next, as shown in FIG. 3C, the metal plate 20 is picked up by a mount head 300. The metal plate 20 is attached to the mount head 300, for example, by vacuum suction.

In the present embodiment, the conductive sheet 30 is arranged below the mount head 300. The conductive sheet 30 is placed on a cushion material 301. The cushion material 301 is configured, for example, of an elastic material. The cushion material 301 is placed on a heater block 302. The heater block 302 heats the conductive sheet 30 via the cushion material 301.

Next, as shown in FIG. 3D, a load is applied on the metal plate 20 when the mount head 300 is lowered. The metal plate 20 presses the conductive sheet 30 with the load. In this stage, a part of the conductive sheet 30 is cut by the lower end corner portion 22, of the metal plate 20, which has the angular shape. Moreover, in this stage, the heater block 302 heats the conductive sheet 30. The heating melts the adhesive agent included in the conductive sheet 30. Thereby, the part of the conductive sheet 30 is bonded onto the bottom surface of the metal plate 20.

Next, as shown in FIG. 3E, when the mount head 300 rises, the metal plate 20 also rises. Thereby, the portion, of the conductive sheet 30, which is bonded onto the bottom surface of the metal plate 20 is cut off from a portion, of the conductive sheet 30, which is not bonded to the metal plate 20.

In the final stage, as shown in FIG. 1, the metal plate 20 is mounted on the semiconductor chip 10 via the conductive sheet 30. In this stage, the metal plate 20 is mounted such that the n-type emitter layers 16 of the semiconductor chip 10 are electrically connected to the metal plate 20 via the conductive sheet 30. Thereby, the semiconductor device 1 shown in FIG. 1 is completed.

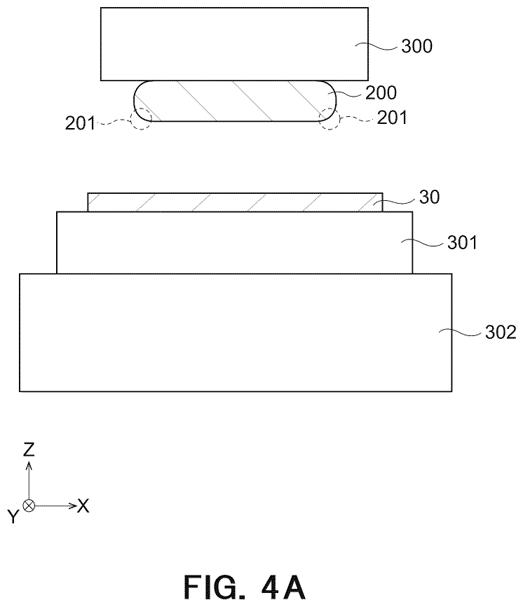

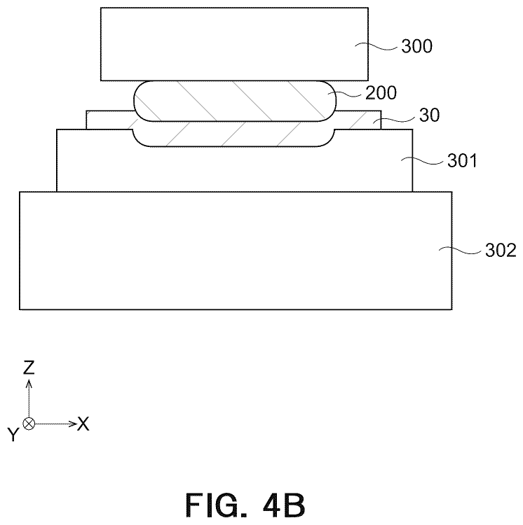

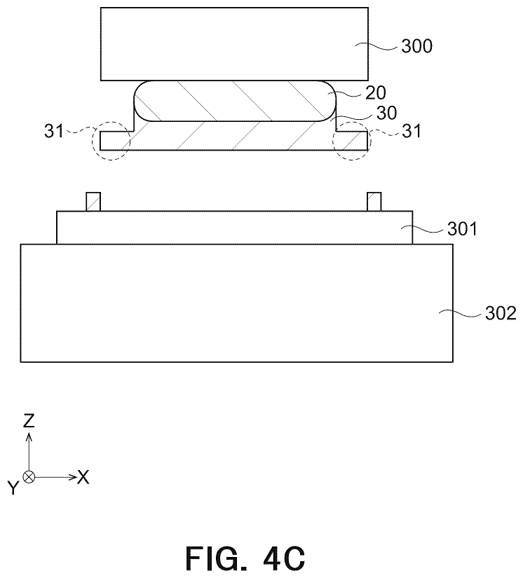

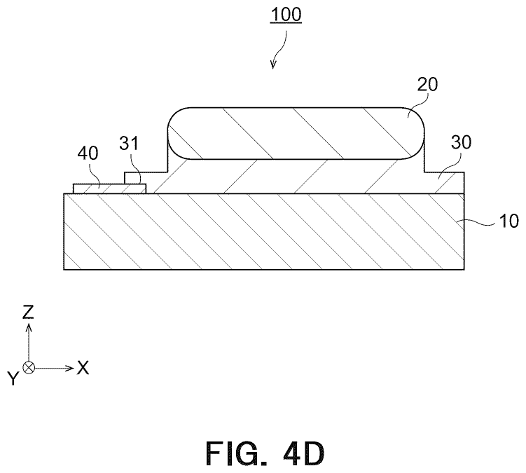

Herein, with reference to FIG. 4A to FIG. 4D, manufacturing steps for a semiconductor device according to a comparative example compared with the aforementioned semiconductor device 1 according to the first embodiment are described.

First, as shown in FIG. 4A, the metal plate 200 is picked up by the mount head 300. In the comparative example, the aforementioned step portion 21 described for the first embodiment is not formed on the metal plate 200. Therefore, the metal plate 200 is picked up by the mount head 300 in the state where the rounded lower end corner portion 201 remains.

Next, as shown in FIG. 4B, a load is applied on the metal plate 200 when the mount head 300 is lowered. The metal plate 200 presses the conductive sheet 30 with the load. In this stage, since the lower end corner portion 201 of the metal plate 200 has a rounded shape, the conductive sheet 30 is scarcely cut.

Since also in the comparative example, the heater block 302 heats the conductive sheet 30 when the metal plate 200 presses the conductive sheet 30, the adhesive agent included in the conductive sheet 30 melts. Thereby, a part of the conductive sheet 30 is bonded onto the bottom surface of the metal plate 200.

Next, as shown in FIG. 4C, when the mount head 300 rises, the metal plate 20 also rises. As mentioned above, in the comparative example, the conductive sheet 30 is scarcely cut by the metal plate 200. Therefore, while the metal plate 20 is rising, there arise burrs 31 of the conductive sheet 30 at the lower end corner portion 201 of the metal plate 200.

In the final stage, as shown in FIG. 4D, the metal plate 200 is mounted on the semiconductor chip 10 via the conductive sheet 30. Thereby, a semiconductor device 100 according to the comparative example is completed. In the semiconductor device 100, the conductive sheet 30 and the control terminal 40 essentially need to be electrically insulated from each other.

Nevertheless, as shown in FIG. 4D, in the semiconductor device 100 manufactured through the aforementioned manufacturing steps, there can be a case where some burrs 31 of the conductive sheet 30 come into contact with the control terminal 40. In this case, short circuit failure occurs.

Against this, in the first embodiment, the step portion 21 is formed on the lateral surface of the metal plate 20, and the lower end corner portion 22 of the step portion 21 has the angular shape, as mentioned above. This makes the lower end corner portion 22 readily cut the conductive sheet 30 when the metal plate 20 presses the conductive sheet 30. Thereby, the burrs 31 of the conductive sheet 30 scarcely arise. As a result, the conductive sheet 30 scarcely comes into contact with the control terminal 40, and hence, short circuit failure scarcely occurs.

Accordingly, according to the present embodiment, reliability can be improved while thermal conductivity is improved.

Notably, in the present embodiment, as shown in FIG. 1, when the conductive sheet 30 together with the metal plate 20 is mounted on the semiconductor chip 10, a part of the conductive sheet 30 slightly protrudes outward from the bottom surface of the metal plate 20. Nevertheless, since the protruding conductive sheet 30 does not reach the control terminal 40, electric insulation between both is sufficiently secured. Thereby, short circuit failure can be sufficiently prevented.

### Second Embodiment

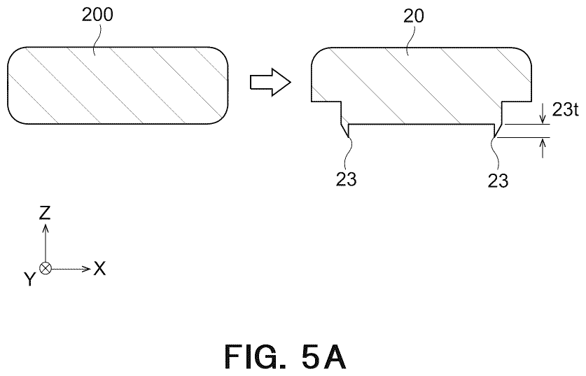

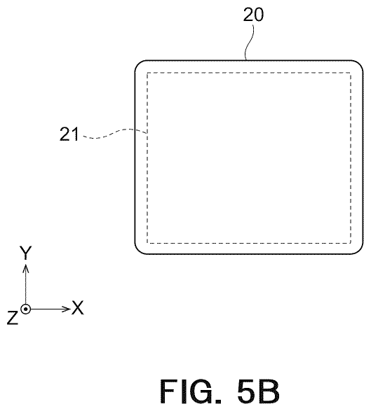

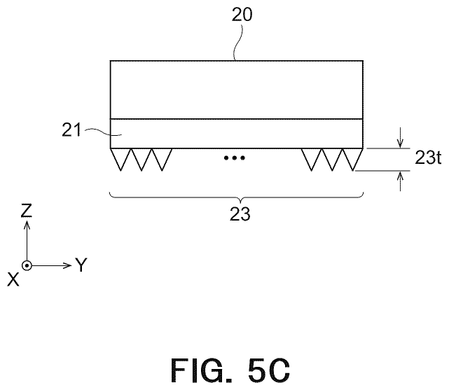

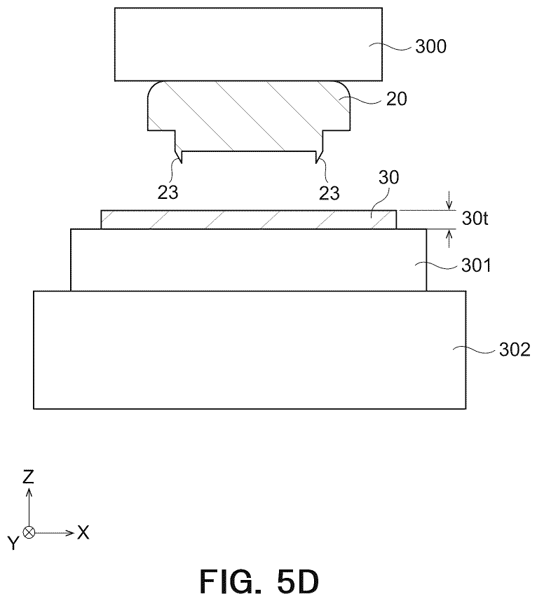

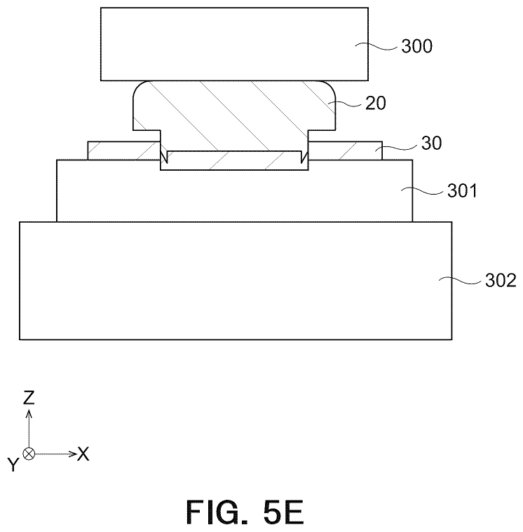

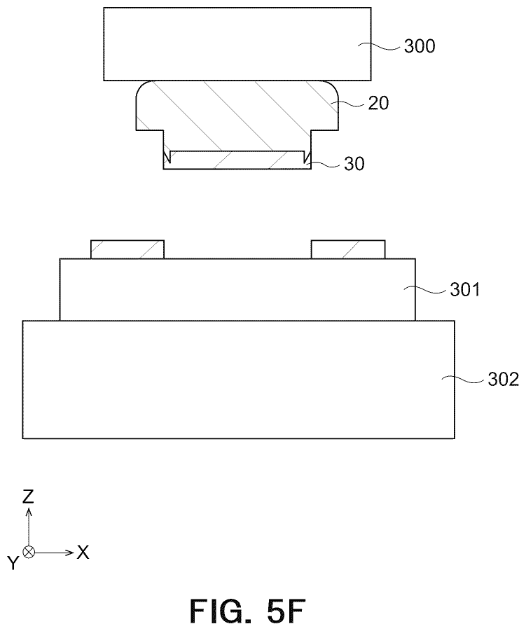

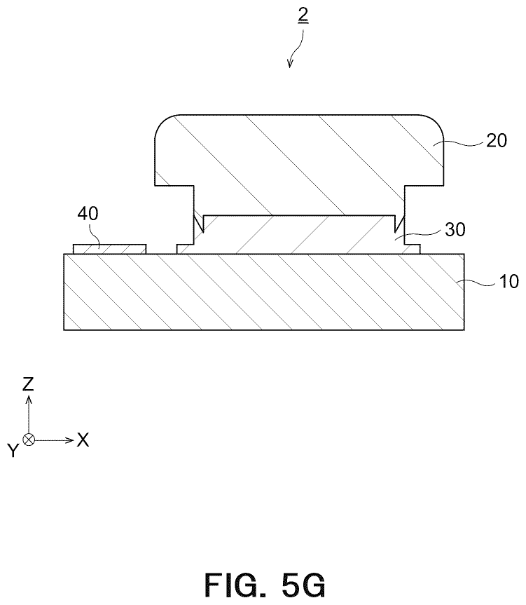

A second embodiment is different from the first embodiment in the structure of the metal plate 20. Herein, a manufacturing method of a semiconductor device according to the second embodiment is described with reference to FIG. 5A to FIG. 5G. Notably, in the present embodiment, the similar constituents to those of the semiconductor device 1 according to the first embodiment are given the same signs, and their detailed description is omitted.

First, as shown in FIG. 5A, the rounded lower end corner portion 201 of the metal plate 200 is cut off, for example, by laser machining. Thereby, as with the first embodiment, the step portion 21 is formed. As shown in FIG. 5B which is a plan view, the step portion 21 is formed around the whole circumference of the lateral surface of the metal plate 20.

In the present embodiment, projection portions 23 are also simultaneously formed when the step portion 21 is formed by laser machining. The projection portions 23 protrude downward in a vertical direction (−Z-direction) from the lower end portion of the step portion 21, and the tip of each of them is sharp at an acute angle. Moreover, an example of a thickness “23t” (length in the Z-direction) of the projection portions 23 is in a range of one-third to three-thirds a thickness “30t” of the conductive sheet 30.

As shown in FIG. 5C, the projection portions 23 each having the shape as above are consecutively arranged around the whole circumference of the lower end portion of the step portion 21. Accordingly, the plurality of projection portions 23 are arranged into a sawtooth shape on the lower end portion of the step portion 21. Notably, FIG. 5C is a lateral view of the metal plate 20 according to the present embodiment as viewed from the YZ-plane.

Next, as shown in FIG. 5D, the metal plate 20 is picked up by the mount head 300. The conductive sheet 30 is arranged below the mount head 300. The conductive sheet 30 is placed on the cushion material 301. The cushion material 301 is placed on the heater block 302. The heater block 302 heats the conductive sheet 30 via the cushion material 301.

Next, as shown in FIG. 5E, a load is applied on the metal plate 20 when the mount head 300 is lowered. The metal plate 20 presses the conductive sheet 30 with the load. In this stage, a part of the conductive sheet 30 is cut by the projection portions 23 formed on the metal plate 20. In this stage, since the heater block 302 heats the conductive sheet 30, the part of the conductive sheet 30 is bonded onto the bottom surface of the metal plate 20.

Next, as shown in FIG. 5F, when the mount head 300 rises, the metal plate 20 also rises. Thereby, the portion, of the conductive sheet 30, which is bonded onto the bottom surface of the metal plate 20 is cut off from a portion, of the conductive sheet 30, which is not bonded to the metal plate 20.

In the final stage, as shown in FIG. 5G, the metal plate 20 is mounted on the semiconductor chip 10 via the conductive sheet 30. Thereby, a semiconductor device 2 according to the second embodiment is completed.

In the present embodiment, the step portion 21 is formed on the lateral surface of the metal plate 20, and the projection portions 23 are formed at the lower end portion of the step portion 21. Therefore, when the metal plate 20 presses the conductive sheet 30, the projection portions 23 cut the conductive sheet 30. Since the tip portion of each projection portion 23 has a sharp shape with an acute angle, the conductive sheet 30 is readily cut as comparted with the lower end corner portion 22 described for the first embodiment. As a result, since the burrs 31 of the conductive sheet 30 more scarcely arise, short circuit failure is further reduced.

Accordingly, also with the present embodiment, reliability can be improved while thermal conductivity is improved.

Notably, also in the present embodiment, as shown in FIG. 5G, when the conductive sheet 30 together with the metal plate 20 is mounted on the semiconductor chip 10, a part of the conductive sheet 30 slightly protrudes outward from the bottom surface of the metal plate 20. Nevertheless, since the protruding conductive sheet 30 does not reach the control terminal 40, electric insulation between both is sufficiently secured. Thereby, short circuit failure can be sufficiently prevented.

### Third Embodiment

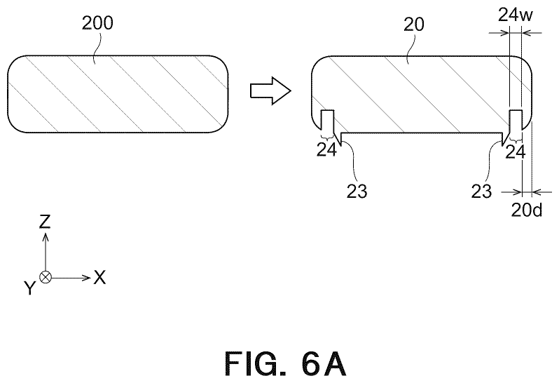

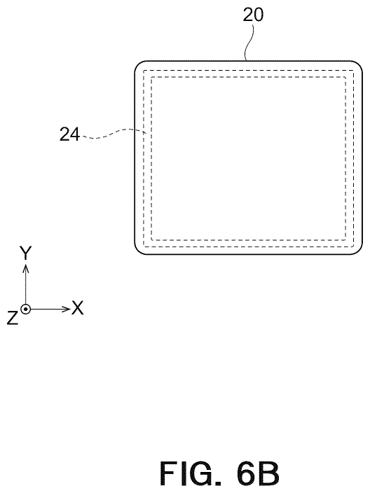

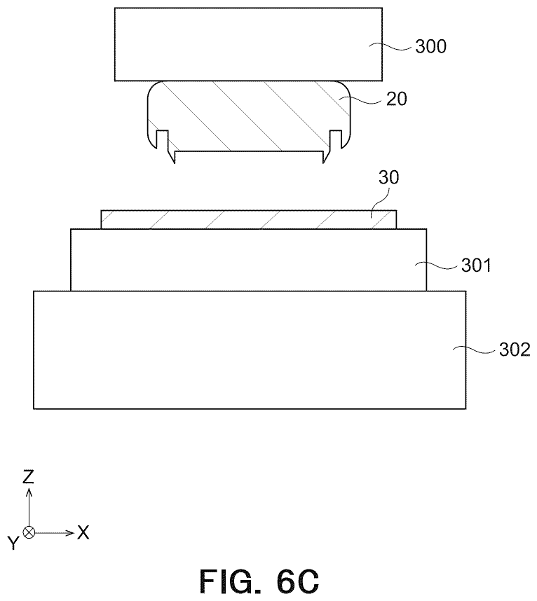

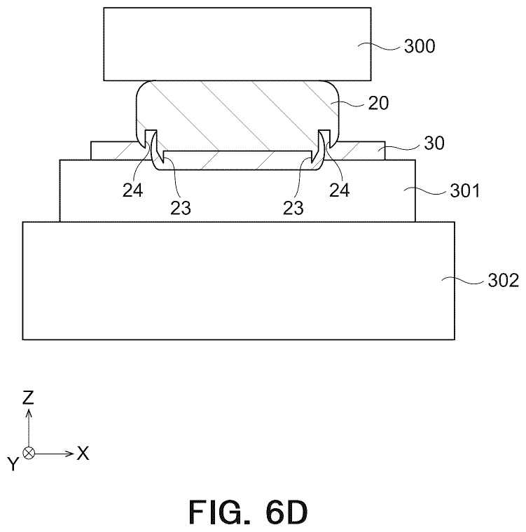

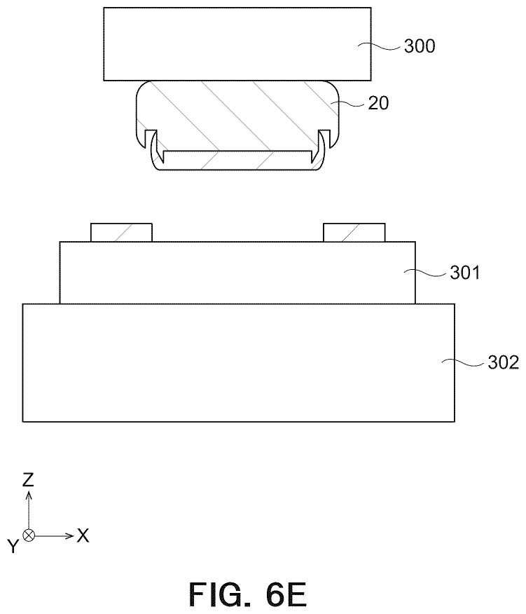

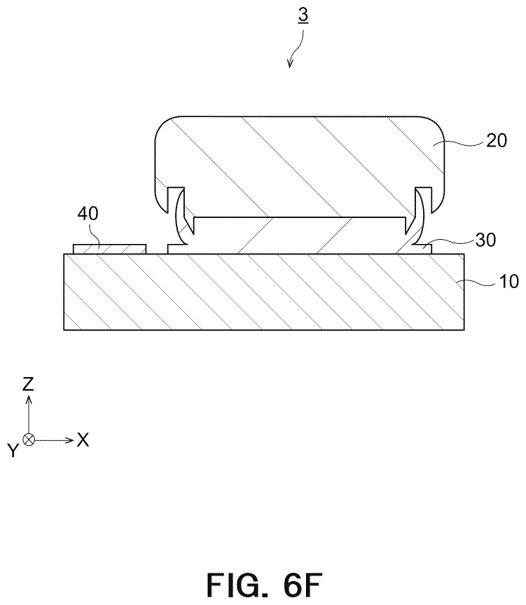

A third embodiment is different from the first embodiment and the second embodiment in the structure of the metal plate 20. Herein, a manufacturing method of a semiconductor device according to the third embodiment is described with reference to FIG. 6A to FIG. 6F. Notably, in the present embodiment, the similar constituents to those of the semiconductor device 1 according to the first embodiment and the semiconductor device 2 according to the second embodiment are given the same signs, and their detailed description is omitted.

First, as shown in FIG. 6A, the metal plate 200 is processed into the metal plate 20 in which the projection portions 23 and a groove portion 24 are formed, for example, by laser machining. The projection portions 23 are simultaneously formed when the groove portion 24 is formed. The projection portions 23 protrude downward in the vertical direction (−Z-direction) from the bottom surface of the metal plate 20, and the tip of each of them is sharp at an acute angle. Moreover, as with the second embodiment, an example of the thickness “23t” (length in the Z-direction) of the projection portions 23 is in a range of one-third to three-thirds the thickness “30t” of the conductive sheet 30. The projection portions 23 each having the shape as above are consecutively arranged around the whole circumference of the bottom surface of the metal plate 20.

On the other hand, the groove portion 24 is formed outward of the projection portions 23. The groove portion 24 is recessed upward from the bottom surface of the metal plate 20. An example of a width “24w” of the groove portion 24 is in a range of 0.1 to 0.5 mm. Moreover, an example of a distance “20d” from an end portion of the metal plate 20 to an outer circumferential end of the groove portion 24 is in a range of 0.02 to 0.5 mm. Moreover, as shown in FIG. 6B, the groove portion 24 is continuously formed around the whole circumference of the bottom surface of the metal plate 20 outward of the projection portions 23.

Next, as shown in FIG. 6C, the metal plate 20 is picked up by the mount head 300. The conductive sheet 30 is arranged below the mount head 300. The conductive sheet 30 is placed on the cushion material 301. The cushion material 301 is placed on the heater block 302. The heater block 302 heats the conductive sheet 30 via the cushion material 301.

Next, as shown in FIG. 6D, a load is applied on the metal plate 20 when the mount head 300 is lowered. The metal plate 20 presses the conductive sheet 30 with the load. In this stage, a part of the conductive sheet 30 is cut by the projection portions 23 formed on the metal plate 20. Moreover, the conductive sheet 30 pushed out with the pressing by the metal plate 20 is limited within the groove portion 24 provided outward of the projection portions 23.

Notably, as with the first embodiment and the second embodiment, also with the present embodiment, since the heater block 302 heats the conductive sheet 30 when the metal plate 20 presses the conductive sheet 30, the part of the conductive sheet 30 is bonded onto the bottom surface of the metal plate 20.

Next, as shown in FIG. 6E, when the mount head 300 rises, the metal plate 20 also rises. Thereby, the portion, of the conductive sheet 30, which is bonded onto the bottom surface of the metal plate 20 is cut off from a portion, of the conductive sheet 30, which is not bonded to the metal plate 20.

In the final stage, as shown in FIG. 6F, the metal plate 20 and the conductive sheet 30 are mounted on the semiconductor chip 10. Thereby, a semiconductor device 3 according to the third embodiment is completed.

In the present embodiment, the projection portions 23 and the groove portion 24 are formed on the bottom surface of the metal plate 20. Therefore, when the metal plate 20 presses the conductive sheet 30, the projection portions 23 cut the conductive sheet 30. Since the tip portion of each projection portion 23 has a sharp shape with an acute angle, the conductive sheet 30 is readily cut as compared with the first embodiment. Moreover, the groove portion 24 restricts the conductive sheet 30 pushed out when the projection portions 23 cut the conductive sheet 30 from spreading. As a result, the burrs 31 of the conductive sheet 30 more scarcely arise than in the second embodiment.

Accordingly, also with the present embodiment, reliability can be improved while thermal conductivity is improved.

Notably, also in the present embodiment, as shown in FIG. 6F, when the conductive sheet 30 together with the metal plate 20 is mounted on the semiconductor chip 10, a part of the conductive sheet 30 slightly protrudes outward from the bottom surface of the metal plate 20. Nevertheless, since the protruding conductive sheet 30 does not reach the control terminal 40, electric insulation between both is sufficiently secured. Thereby, short circuit failure can be sufficiently prevented.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a semiconductor chip;
a conductive sheet provided on the semiconductor chip; and
a metal plate provided on the conductive sheet, wherein
the metal plate has a step portion that is provided on a lateral surface, or a groove portion that is provided on a bottom surface.

2. The semiconductor device according to claim 1, wherein
the metal plate has the step portion, and
a lower end corner portion of the step portion has an angular shape.

3. The semiconductor device according to claim 1, wherein the metal plate has the step portion and a projection portion that is provided at a lower end portion of the step portion.

4. The semiconductor device according to claim 1, wherein the metal plate has the groove portion and a projection portion that is provided inward of the groove portion on the bottom surface.

5. The semiconductor device according to claim 1, wherein
the metal plate is a molybdenum plate, and
the conductive sheet is a sintered sheet of silver or copper.

6. The semiconductor device according to claim 1, further comprising
a control terminal provided on the semiconductor chip, wherein
the control terminal controls drive of the semiconductor chip.

7. The semiconductor device according to claim 6, wherein the semiconductor chip is an IEGT (Injection Enhanced Gate Transistor) chip having a gate electrode electrically connected to the control terminal.

8. The semiconductor device according to claim 4, wherein a width of the groove portion is in a range of 0.1 to 0.5 mm.

9. The semiconductor device according to claim 4, wherein a distance from an end portion of the metal plate to an outer circumferential end of the groove portion is in a range of 0.02 to 0.5 mm.

10. The semiconductor device according to claim 4, wherein a thickness of the projection portion is in a range of one-third to three-thirds a thickness of the conductive sheet.

11. A manufacturing method of a semiconductor device, comprising:
forming a step portion on a lateral surface of a metal plate, or forming a groove portion on a bottom surface of the metal plate;
by pressing the metal plate onto a conductive sheet, bonding the conductive sheet onto the bottom surface of the metal plate; and
mounting the metal plate on a semiconductor chip via the conductive sheet.

12. The manufacturing method of a semiconductor device according to claim 11, wherein the step portion is formed on the lateral surface of the metal plate, and a projection portion is formed at a lower end portion of the step portion.

13. The manufacturing method of a semiconductor device according to claim 11, wherein the groove portion is formed on the bottom surface of the metal plate, and a projection portion is formed inward of the groove portion on the bottom surface.

14. The manufacturing method of a semiconductor device according to claim 11, wherein
the metal plate is a molybdenum plate, and
the conductive sheet is a sintered sheet of silver or copper.

15. The manufacturing method of a semiconductor device according to claim 11, comprising forming a control terminal configured to control drive of the semiconductor chip on the semiconductor chip.

16. The manufacturing method of a semiconductor device according to claim 11, wherein the semiconductor chip is an IEGT (Injection Enhanced Gate Transistor) chip having a gate electrode electrically connected to the control terminal.
